(19) United States
(12) Patent Application Publication
(10) Pub. No.: US 2023/0122901 A1
(43) Pub. Date: Apr. 20, 2023

(54) FAULT TOLERANT SYSTEM FOR TRANSMITTING DISTRIBUTED DATA AND DYNAMIC RESOURCE ADJUSTMENT METHOD THEREOF

(71) Applicant: INSTITUTE FOR INFORMATION INDUSTRY, TAIPEI CITY (TW)

(72) Inventors: Jiann-Wen WANG, TAIPEI CITY (TW); Zheng-Xiu WU, TAIPEI CITY (TW); Wen-To HUANG, TAIPEI CITY (TW); Li-Hao CHIANG, TAIPEI CITY (TW)

(21) Appl. No.: 17/524,431

(22) Filed: Nov. 11, 2021

(30) Foreign Application Priority Data
Oct. 14, 2021 (TW) 110138103

(51) Int. Cl. G06F 11/14; G06F 3/06

(52) U.S. Cl. CPC G06F 11/1469; G06F 3/065; G06F 3/0619; G06F 3/0673; H03M 7/30

(57) ABSTRACT

The present invention includes a main device and a backup device. A first backup system element of the main device is used to determine whether a first estimated time is less than a second estimated time. The first estimated time is a time period for directly transmitting pending data. The second estimated time is a time period for transmitting the pending data after the pending data is compressed by a current compression algorithm. If yes, the first backup system element directly transmits the pending data to a second backup system element of the backup device. If not, the first backup system element compresses the pending data by the current compression algorithm, updates the pending data and the current compression algorithm, and re-determines whether the first estimated time is less than the second estimated time. The present invention improves availability of data backup when a network bandwidth is poor.

### CROSS-REFERENCE TO RELATED APPLICATION(S

This application claims the priority benefit of TW application serial No. 110138103 filed on October 14^{th}, 2021, the entirety of which is hereby incorporated by reference herein and made a part of specification.

### BACKGROUND OF THE INVENTION

### 1. Field of the Invention

The present invention relates to a fault tolerant system for transmitting data and a resource adjustment method thereof, more particularly a fault tolerant system for transmitting distributed data and a dynamic resource adjustment method thereof.

### 2. Description of the Related Art

As information service becomes an essential part of life necessities, enterprises and customers increasingly demand for service availability free of interruption. A fault tolerant virtual machine thus presents an important technology for providing great service availabilities.

The fault tolerant technique of a virtual machine is able to create a completely synchronized warm backup of an application system without cluster or high availability in a backup real device. As a result, when an original real device fails at any given time while executing applications, the execution of applications on a virtual machine of the original device is instantaneously transferred to a virtual machine of the backup real device for continuous execution, and thus a service in execution is free from interruptions.

The fault tolerant technique of the virtual machine achieves instantaneous transfers by instantly copying virtual machine status of memories, hard drive image files, and processors, etc. This however exhausts a wide and stable bandwidth, and as a result, often causes resource distribution problems for both software and hardware. By exhausting the bandwidth, backing up for multiple virtual machines simultaneously or backing up across long distance also becomes nearly impossible.

A current dynamic transfer technology however can yet to be directly applied to the fault tolerant system, as the current dynamic transfer technology lacks a balancing strategy between delays caused by continuous backups and exhausting resources. Therefore, a current fault tolerant virtual machine needs further improvements.

### SUMMARY OF THE INVENTION

The present invention provides a fault tolerant system for transmitting distributed data and a dynamic resource adjustment method thereof. Under a network environment with changing bandwidths, the present invention is able to detect and dynamically adjust operating of the fault tolerant system in a short amount of time. This way the present invention is able to fully utilize a processor and network bandwidth resources, and the present invention allows the fault tolerant system to be deployed in complicated and real environments.

The dynamic resource adjustment method of the fault tolerant system for transmitting distributed data is executed by the fault tolerant system for transmitting distributed data. The dynamic resource adjustment method of the fault tolerant system for transmitting distributed data includes the following steps:
obtaining a backup data segment from a main device;
setting a compression algorithm ordered first in a compression algorithm combination as a current compression algorithm, and setting the backup data segment as pending data; wherein the compression algorithm combination includes multiple compression algorithms in order;
determining whether a first estimated time is less than or equal to a second estimated time; wherein the first estimated time is a time period for directly transmitting the pending data, and the second estimated time is a time period for transmitting the pending data after the pending data is compressed by the current compression algorithm;
when the first estimated time is less than or equal to the second estimated time, sending the pending data to a backup device;
when the first estimated time is greater than the second estimated time, compressing the pending data by the current compression algorithm, and updating the pending data as the compressed pending data;
updating the current compression algorithm as the compression algorithm in the next order in the compression algorithm combination; and re-determining whether the first estimated time is less than or equal to the second estimated time.

The fault tolerant system for transmitting distributed data includes the main device and the backup device.

The main device includes a first backup system element. The first backup system element obtains a backup data segment, sets a current compression algorithm as a compression algorithm ordered first in a compression algorithm combination, and sets the backup data segment as pending data. The compression algorithm combination includes multiple compression algorithms in order.

The backup device includes a second backup system element. The second backup system element connects to the first backup system element. The first backup system element determines whether a first estimated time is less than or equal to a second estimated time. The first estimated time is a time period for directly transmitting the pending data, and the second estimated time is a time period for transmitting the pending data after the pending data is compressed by the current compression algorithm.

When the first estimated time is less than or equal to the second estimated time, the first backup system element sends the pending data to the second backup system element of the backup device, and the second backup system element saves the pending data in the backup device.

When the first estimated time is greater than the second estimated time, the first backup system element compresses the pending data by the current compression algorithm, then updates the pending data as the compressed pending data, updates the current compression algorithm as the compression algorithm in the next order in the compression algorithm combination, and re-determines whether the first estimated time is less than the second estimated time.

When synchronizing, the present invention is able to monitor a network environment of the main device, available processor resources, and operating status of a virtual machine being protected by the present invention. The present invention selects different compression algorithms in real time and dynamically adjusts the synchronization strategy to improve availability of the fault tolerant system when a bandwidth of the network environment is shared or when the bandwidth is poor.

### BRIEF DESCRIPTION OF THE DRAWINGS

FIG. 1 is a flowchart of a first embodiment of a dynamic resource adjustment method of a fault tolerant system for transmitting distributed data of the present invention.

FIG. 2 is a block diagram of the fault tolerant system for transmitting distributed data of the present invention.

FIG. 3 is a flowchart of a second embodiment of the dynamic resource adjustment method of the fault tolerant system for transmitting distributed data of the present invention.

### DETAILED DESCRIPTION OF THE INVENTION

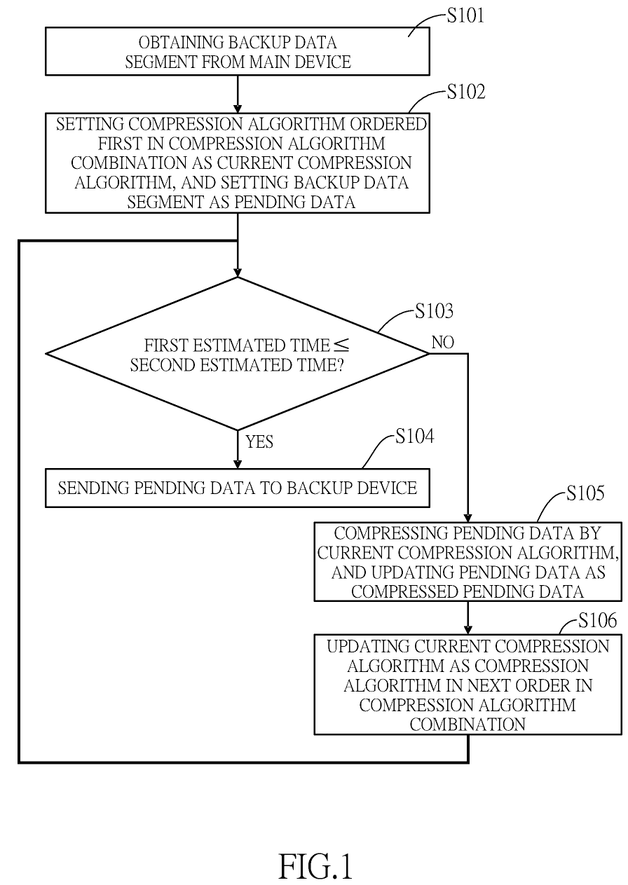

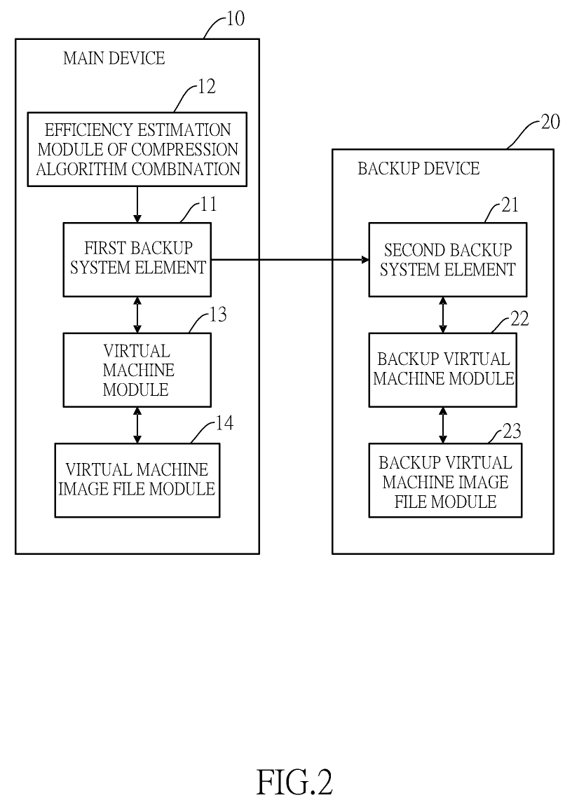

With reference to FIGS. 1 and 2, a dynamic resource adjustment method of a fault tolerant system for transmitting distributed data of the present invention is executed by the fault tolerant system for transmitting distributed data 100. A first embodiment of the dynamic resource adjustment method of the fault tolerant system for transmitting distributed data includes the following steps:
Step S101: obtaining a backup data segment from a main device 10. In the present embodiment, the backup data segment is a starting data segment of a complete backup data of the main device 10. The starting data segment has a size of a specified amount of bytes. Furthermore, the backup data segment is a data segment of a virtual processor of the main device 10, a data segment of a virtual peripheral device, a data segment of a memory, or a data segment of a hard disk image file.
Step S102: setting a compression algorithm ordered first in a compression algorithm combination as a current compression algorithm, and setting the backup data segment as pending data, wherein the compression algorithm combination includes multiple compression algorithms in order. In the present embodiment, the multiple compression algorithms of the compression algorithm combination include a fast compression algorithm, a high compression rate compression algorithm, a memory paging compression algorithm, and a hardware accelerator compression algorithm. For example, the fast compression algorithm can use LZ4 compression algorithm, the high compression rate compression algorithm can use Zstandard (Zstd) compression algorithm, the memory paging compression algorithm can use Run-Length Encoding (RLE) compression algorithm, and the hardware accelerator compression algorithm can use DEFLATE compression algorithm for compressing data.
Step S103: determining whether a first estimated time is less than or equal to a second estimated time, wherein the first estimated time is a time period for directly transmitting the pending data, and the second estimated time is a time period for transmitting the pending data after the pending data is compressed by the current compression algorithm.
Step S104: when the first estimated time is less than or equal to the second estimated time, sending the pending data to a backup device. Since directly sending the pending data saves more time than backing up the pending data, as when the first estimated time is less than or equal to the second estimated time, the pending data is therefore directly sent to the backup device for a backup.
Step S105: when the first estimated time is greater than the second estimated time, compressing the pending data by the current compression algorithm, and updating the pending data as the compressed pending data. Since compressing the pending data by the current compression algorithm and then sending the compressed pending data to the backup device for a backup saves more time than directly sending the pending data to the backup device, as when the first estimated time is greater than the second estimated time, the pending data is therefore compressed by the current compression algorithm first.
Step S106: updating the current compression algorithm as the compression algorithm in the next order in the compression algorithm combination, and re-executing step S103. Since the pending data is already compressed by the current compression algorithm, if the same compression is used again, compression rate would cease to increase. For this reason, step S106 proceeds to update the current compression algorithm as the compression algorithm in the next order in the compression algorithm combination. Upon updating the current compression algorithm, when re-executing step S103, the updated current compression algorithm would be used to re-determine whether the first estimated time is less than or equal to the second estimated time. If the first estimated time is greater than the second estimated time, then the updated current compression algorithm would be used to once more compress the pending data, providing more layers of compression mechanisms for compressing the pending data, increasing compression rate of the pending data, and decreasing transferring time for creating a backup.

With reference to FIG. 2, the fault tolerant system for transmitting distributed data 100 includes a main device 10 and a backup device 20.

The main device 10 includes a first backup system element 11. The first backup system element 11 obtains a backup data segment, sets a compression algorithm ordered first in a compression algorithm combination as a current compression algorithm, and sets the backup data segment as pending data. The compression algorithm combination includes multiple compression algorithms in order.

The backup device 20 includes a second backup system element 21. The second backup system element 21 connects to the first backup system element 11. The first backup system element 11 determines whether a first estimated time is less than or equal to a second estimated time. The first estimated time is a time period for directly transmitting the pending data, and the second estimated time is a time period for transmitting the pending data after the pending data is compressed by the current compression algorithm.

When the first estimated time is less than or equal to the second estimated time, the first backup system element 11 sends the pending data to the second backup system element 21 of the backup device 20, and the second backup system element 21 saves the pending data in the backup device 20.

When the first estimated time is greater than the second estimated time, the first backup system element 11 compresses the pending data by the current compression algorithm, then updates the pending data as the compressed pending data, updates the current compression algorithm as the compression algorithm in the next order in the compression algorithm combination, and re-determines whether the first estimated time is less than the second estimated time.

This way, when synchronizing, the present invention is able to monitor a network environment of the main device 10, available processor resources, and operating status of a virtual machine being protected by the present invention. The present invention selects different compression algorithms in real time and dynamically adjusts the synchronization strategy to improve availability of the fault tolerant system when a bandwidth of the network environment is shared or when the bandwidth is poor.

Furthermore, under a network environment with changing bandwidths, the present invention is able to detect and dynamically adjust operating of the fault tolerant system in a short amount of time. This way the present invention is able to fully utilize a processor and network bandwidth resources.

In other words, compared to prior arts, the present invention is used in a highly instantaneous fault tolerant system. Through monitoring the network environment and analyzing data specifications in real time, the present invention is able to efficiently process data backups of different data types. The present invention is also able to handle sudden network bandwidth changes to sustain the fault tolerant system and to maintain quality of services being protected by the fault tolerant system. For this reason, when a same cable is used or when the network bandwidth is limited, the present invention would still be able to execute fault tolerant backups successfully.

Furthermore, since the fault tolerant system for transmitting distributed data 100 is required to complete several tenths of synchronization processes within a second (s), in other words, compression and transfers need to be completed within couple milliseconds (ms), the present invention uses a selective design of instantaneous multi-layered compression algorithm to avoid negative impact of wrong compression related determinations.

For example, after the first backup system element 11 obtains the backup data segment, the first backup system element 11 calculates the first estimated time as 10 ms for directly transmitting the pending data. The first backup system element 11 further calculates the second estimated time as 9 ms, as 3 ms is estimated for the pending data to be compressed by the current compression algorithm, and as 6 ms is estimated for the compressed pending data to be transferred. Since the first estimated time is greater than the second estimated time, the first backup system element 11 first compresses the pending data, and then updates the pending data and the current compression algorithm. Finally, after the update, the first backup system element 11 re-determines whether the updated first estimated time is less than or equal to the updated second estimated time.

Since both the pending data and the current compression algorithm are updated, the updated first estimated time is then changed to 6 ms, and the updated second estimated time is then changed to 7 ms. As such, the updated first estimated time is less than the updated second estimated time, and therefore the first backup system element 11 would directly transfer the updated pending data.

However, if after the update, the updated first estimated time is still greater than the updated second estimated time, the first backup system element 11 would then use the updated current compression algorithm to further compress the pending data, so as to use multi-layered compression algorithms to compress the pending data, decreasing transferring time for creating a backup.

In addition, the main device 10 further includes a virtual machine module 13 and a virtual machine image file module 14, and the backup device 20 further includes a backup virtual machine module 22 and a backup virtual machine image file module 23. A complete backup data obtained by the first backup system element 11 is a data stored within the virtual machine module 13 and the virtual machine image file module 14. For instance, the complete backup data is specifications and complete status relating to the virtual machine, or information and complete content relating to an image file. Through creating backups from the first backup system element 11 and the second backup system element 21, complete copies of backup is created within the backup virtual machine module 22 and the backup virtual machine image file module 23 of the backup device 20.

The main device 10 also includes an efficiency estimation module of compression algorithm combination 12. The efficiency estimation module of compression algorithm combination 12 is connected to the first backup system element 11. The efficiency estimation module of compression algorithm combination 12 calculates the compression algorithm combination based on a current network bandwidth, a current performance of the main device 10, and a workload estimation.

In other words, the efficiency estimation module of compression algorithm combination 12 measures a throughput of a processor executing algorithms for the main device 10 and a performance indicator of the available network bandwidths to calculate the compression algorithm combination.

The efficiency estimation module of compression algorithm combination 12 re-calculates the compression algorithm combination based on the current network bandwidth, the current performance of the main device 10, and the workload estimation for every passing of a first time duration.

To instantaneously adapt to changes of the network bandwidth and resource changes of the main device 10, for every few seconds, or for the first time duration, the efficiency estimation module of compression algorithm combination 12 would adjust the compression algorithm combination. To adjust the compression algorithm combination, the efficiency estimation module of compression algorithm combination 12 adjusts the order of compression algorithms used, and enhances synchronization reliability when the network bandwidth experiences great changes. In other words, the efficiency estimation module of compression algorithm combination 12 periodically adjusts the compression algorithm combination, so as to dynamically adjust the compression algorithm combination in order to improve availability of the fault tolerant system when a bandwidth of the network environment is shared or when the bandwidth is poor.

For example, the efficiency estimation module of compression algorithm combination 12 first calculates an averaged available bandwidth of a network within a time frame, an averaged compression rate of each data type, and compression time. The efficiency estimation module of compression algorithm combination 12 then further calculates the most suitable compression algorithm combination under the current network bandwidth, the current performance of the main device 10, and the current workload. If the compression algorithm combination is different, the compression algorithm combination will have different compression algorithm orders, as different compression algorithms suit different kinds of network environments. For instance, when a network environment struggles to spare bandwidths, the order of compression algorithms used would be suitable for decreasing compression time, and when a network environment has ample bandwidths to spare, the order of compression algorithms used would be suitable for decreasing network resource exhaustion.

Furthermore, the efficiency estimation module of compression algorithm combination 12 can also calculate the compression algorithm combination according to a data type of the backup data segment.

For example, when the fault tolerant system free of a single point of failure is put into practice, changes of few different types of virtual machine data would need to be synchronized. Since different types of virtual machine data each have individualized properties as well as suitable compression algorithms, the efficiency estimation module of compression algorithm combination 12 further applies different kinds of the compression algorithm combinations according to different data types of the backup data segment.

For instance, when the virtual machine data type is a virtual processor data, since data size of the virtual processor data is small, the virtual processor data is directly transferred without a need for compression. When the virtual machine data type is a virtual peripheral device data, and the virtual peripheral device data is relatively unchanged, a differential compression algorithm is applied. When the virtual machine data type is the virtual peripheral device data, and the virtual peripheral device data is often changed, RLE compression algorithm is first used to compress the virtual peripheral device data, and the compressed virtual peripheral device data is then transferred. When the virtual machine data type is a memory data, a generalized fast compression algorithm is used to compress the memory data. When the virtual machine data type is a hard disk image file data, the generalized fast compression algorithm is also used to compress the hard disk image file data. In the present embodiment, the generalized fast compression algorithm can use LZ4 compression algorithm, Zstd compression algorithm, RLE compression algorithm, or DEFLATE compression algorithm for compressing data. In another embodiment, the fast compression algorithm is free to be elsewise.

In the present embodiment, the efficiency estimation module of compression algorithm combination 12 is first applied to an experimental bandwidth environment or a real-life bandwidth environment, to test and record compression rates of different data types under different data loads. After the experiments, the efficiency estimation module of compression algorithm combination 12 is able to produce the compression algorithm combination as designed. In other words, the efficiency estimation module of compression algorithm combination 12 is able to take in the current network bandwidth and compression capabilities, and produce the compression algorithm combination suitable when synchronizing backups.

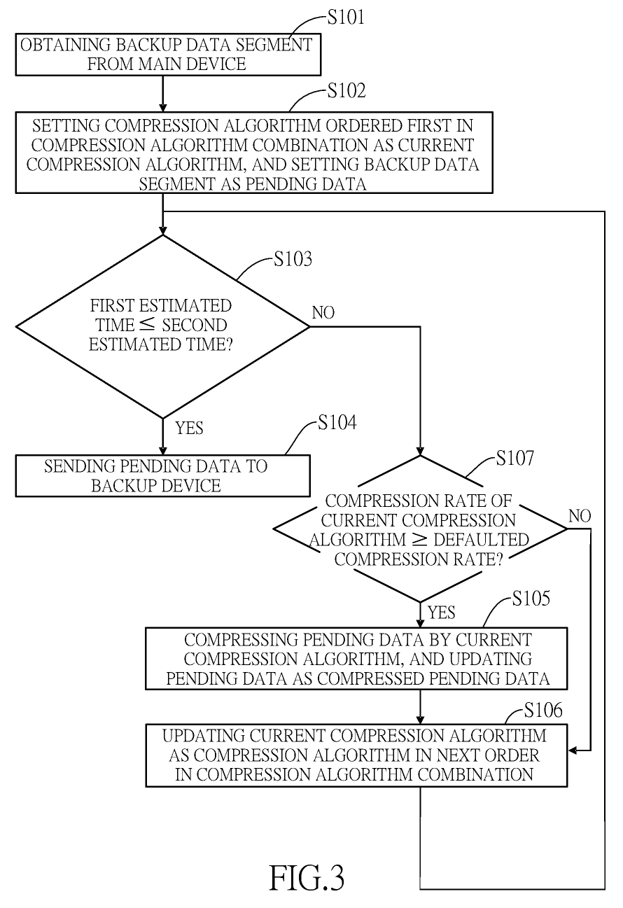

With reference to FIG. 3, in a second embodiment of the present invention, the following step is further included:

Step S107: when the first estimated time is greater than the second estimated time, determining whether a compression rate of the current compression algorithm is higher than or equal to a defaulted compression rate. When the compression rate of the current compression algorithm is higher than or equal to the defaulted compression rate, execute step S105 and step S106, and then re-execute step S103. When the compression rate of the current compression algorithm is lower than the defaulted compression rate, first execute S106 before re-executing step S103.

Similarly, when the fault tolerant system for transmitting distributed data 100 determines that the first estimated time is greater than the second estimated time, the first backup system element 11 first determines whether a compression rate of the current compression algorithm is higher than or equal to a defaulted compression rate.

When the compression rate of the current compression algorithm is higher than or equal to the defaulted compression rate, the first backup system element 11 only then compresses the pending data by the current compression algorithm, updates the pending data as the compressed pending data, updates the current compression algorithm to be the next compression algorithm in order in the compression algorithm combination, and re-determines whether the first estimated time is less than the second estimated time.

When the compression rate of the current compression algorithm is lower than the defaulted compression rate, then the first backup system element 11 updates the current compression algorithm to be the next compression algorithm in order in the compression algorithm combination, and re-determines whether the first estimated time is less than the second estimated time.

In addition, regarding data properties of fault tolerant synchronized data, in the present embodiment, the present invention tries to compress each of the starting data segment of the complete backup data for a specified amount of bytes.

For example, for the starting data segment of the complete backup data, the first 16 Kbytes of the complete backup data is assigned as the backup data segment. By compressing the backup data segment first, the present invention is able to gauge whether compressing with the current compression algorithm satisfies the defaulted compression rate. This way the present invention minimizes chances of compressing ineffectively.

The above details only a few embodiments of the present invention, rather than imposing any forms of limitation to the present invention. Any professionals in related fields of expertise relating to the present invention, within the limitations of what is claimed, are free to make equivalent adjustments regarding the embodiments mentioned above. However, any simple adjustments and equivalent changes made without deviating from the present invention would be encompassed by what is claimed for the present invention.

1. A dynamic resource adjustment method of a fault tolerant system for transmitting distributed data, comprising:
obtaining a backup data segment from a main device;
setting a compression algorithm ordered first in a compression algorithm combination as a current compression algorithm, and setting the backup data segment as pending data; wherein the compression algorithm combination includes multiple compression algorithms in order;
determining whether a first estimated time is less than or equal to a second estimated time; wherein the first estimated time is a time period for directly transmitting the pending data, and the second estimated time is a time period for transmitting the pending data after the pending data is compressed by the current compression algorithm;
when the first estimated time is less than or equal to the second estimated time, sending the pending data to a backup device; and
when the first estimated time is greater than the second estimated time, compressing the pending data by the current compression algorithm, and updating the pending data as the compressed pending data; and
updating the current compression algorithm as the compression algorithm in the next order in the compression algorithm combination; and re-determining whether the first estimated time is less than or equal to the second estimated time.

2. The dynamic resource adjustment method of the fault tolerant system for transmitting distributed data as claimed in claim 1, comprising:
when the first estimated time is greater than the second estimated time, determining whether a compression rate of the current compression algorithm is higher than or equal to a defaulted compression rate;
when the compression rate of the current compression algorithm is higher than or equal to the defaulted compression rate, compressing the pending data by the current compression algorithm, updating the pending data as the compressed pending data, updating the current compression algorithm as the compression algorithm in the next order in the compression algorithm combination, and re-determining whether the first estimated time is less than the second estimated time; and
when the compression rate of the current compression algorithm is lower than the defaulted compression rate, updating the current compression algorithm as the compression algorithm in the next order in the compression algorithm combination, and re-determining whether the first estimated time is less than the second estimated time.

3. The dynamic resource adjustment method of the fault tolerant system for transmitting distributed data as claimed in claim 1, wherein
the backup data segment is a starting data segment of a complete backup data of the main device, and the starting data segment has a size of a specified amount of bytes.

4. The dynamic resource adjustment method of the fault tolerant system for transmitting distributed data as claimed in claim 1, further comprising:
calculating a compression algorithm combination based on a current network bandwidth, a current performance of the main device, and a workload estimation by an efficiency estimation module of compression algorithm combination.

5. The dynamic resource adjustment method of the fault tolerant system for transmitting distributed data as claimed in claim 4, wherein
the efficiency estimation module of compression algorithm combination recalculates the compression algorithm combination based on the current network bandwidth, the current performance of the main device, and the workload estimation for each passing of a first time duration.

6. The dynamic resource adjustment method of the fault tolerant system for transmitting distributed data as claimed in claim 4, wherein
the efficiency estimation module of compression algorithm combination further calculates the compression algorithm combination according to a data type of the backup data segment.

7. The dynamic resource adjustment method of the fault tolerant system for transmitting distributed data as claimed in claim 1, wherein
the backup data segment is a data segment of a virtual processor of the main device, a data segment of a virtual peripheral device, a data segment of a memory, or a data segment of a hard disk image file.

8. A fault tolerant system for transmitting distributed data, comprising:
a main device, comprising a first backup system element; wherein the first backup system element obtains a backup data segment, sets a compression algorithm ordered first in a compression algorithm combination, and sets the backup data segment as pending data; wherein the compression algorithm combination includes multiple compression algorithms in order;
a backup device, comprising a second backup system element; wherein the second backup system element connects to the first backup system element;
wherein the first backup system element determines whether a first estimated time is less than or equal to a second estimated time; wherein the first estimated time is a time period for directly transmitting the pending data, and the second estimated time is a time period for transmitting the pending data after the pending data is compressed by the current compression algorithm;
wherein when the first estimated time is less than or equal to the second estimated time, the first backup system element sends the pending data to the second backup system element of the backup device, and the second backup system element saves the pending data in the backup device;
wherein when the first estimated time is greater than the second estimated time, the first backup system element compresses the pending data by the current compression algorithm, updates the pending data as the compressed pending data, updates the current compression algorithm as the compression algorithm in the next order in the compression algorithm combination, and re-determines whether the first estimated time is less than the second estimated time.

9. The fault tolerant system for transmitting distributed data as claimed in claim 8, wherein
when determined that the first estimated time is greater than the second estimated time, the first backup system element first determines whether a compression rate of the current compression algorithm is higher than or equal to a defaulted compression rate;
wherein when the compression rate of the current compression algorithm is higher than or equal to the defaulted compression rate, the first backup system element only then compresses the pending data by the current compression algorithm, updates the pending data as the compressed pending data, updates the current compression algorithm to be the next compression algorithm in order in the compression algorithm combination, and re-determines whether the first estimated time is less than the second estimated time;
wherein when the compression rate of the current compression algorithm is lower than the defaulted compression rate, then the first backup system element updates the current compression algorithm to be the next compression algorithm in order in the compression algorithm combination, and re-determines whether the first estimated time is less than the second estimated time.

10. The fault tolerant system for transmitting distributed data as claimed in claim 8, wherein
the backup data segment is a starting data segment of a complete backup data of the main device, and the starting data segment has size of a specified amount of bytes.

11. The fault tolerant system for transmitting distributed data as claimed in claim 8, further comprising:
an efficiency estimation module of compression algorithm combination, connected to the first backup system element; wherein the efficiency estimation module of compression algorithm combination calculates the compression algorithm combination based on a current network bandwidth, a current performance of the main device, and a workload estimation.

12. The fault tolerant system for transmitting distributed data as claimed in claim 11, wherein
the efficiency estimation module of compression algorithm combination recalculates the compression algorithm combination based on the current network bandwidth, the current performance of the main device, and the workload estimation for each passing of a first time duration.

13. The fault tolerant system for transmitting distributed data as claimed in claim 11, wherein
the efficiency estimation module of compression algorithm combination further calculates the compression algorithm combination according to a data type of the backup data segment.

14. The fault tolerant system for transmitting distributed data as claimed in claim 8, wherein
the backup data segment is a data segment of a virtual processor of the main device, a data segment of a virtual peripheral device, a data segment of a memory, or a data segment of a hard disk image file.
